(19) United States
(12) Patent Application Publication
(10) Pub. No.: US 2024/0238888 A1
(43) Pub. Date: Jul. 18, 2024

(54) SOLDER PRINTING APPARATUS

(71) Applicant: TCS ENGINEERING & AUTOMATION SDN. BHD., Simpang Ampat (MY)

(72) Inventor: Tung CHOR SEN, Permatang Pauh (MY)

(21) Appl. No.: 18/561,990

(22) PCT Filed: Apr. 26, 2022
(86) PCT No.: PCT/MY2022/050029

§ 371 Date: Nov. 17, 2023

(30) Foreign Application Priority Data
May 20, 2021 (MY) PI2021002796

(51) Int. Cl. B23K 3/08; H05K 3/34

(52) U.S. Cl. CPC B23K 3/087; H05K 3/34

(57) ABSTRACT

The present invention presents a solder printing apparatus comprising a clamping mechanism (100), and a position adjusting mechanism. The clamping mechanism (100) comprises a mounting base (130), a lead screw (142), one or more clamp base (110), and one or more adjustable height stopper (120) for locating and clamping. The position adjusting mechanism comprises an adjustment for X direction positioning (150), an adjustment for Y direction positioning (160), an adjustment for Z direction positioning (170), and an adjustment for rotation position about the Z axis (180), each having a turn knob with a micrometer scale, as well as, a position indicator (152, 162, 172).

### FIELD OF INVENTION

The present invention generally relates to an apparatus for printing solder balls on an electrode on a surface of a substrate.

### BACKGROUND OF THE INVENTION

This section is intended only to provide background information pertaining to the similar field of the present invention, and may be used only to enhance the understanding of the present invention and not as admissions of prior art.

Conventional solutions for printed circuit board (PCB) substrate solder printing provide a simple clamping mechanism or a template with cut outs shaped to fit the PCB. Where simple clamping mechanisms clamp either the sides or corners of a PCB to hold the PCB in position. When changing between the maximum and minimum size PCB, the clamps need to travel a relatively large displacement. At maximum size position, the clamp is displaced far from the center of the solder printing apparatus. As such, parts of the clamp can extend beyond the footprint of the solder printing apparatus. Hence, requiring a larger workspace to operate.

Another approach is the use of templates. The use of templates to position a PCB requires an inventory of many templates to accommodate various sizes. However, storage space is required to store the inventory of templates.

In addition to holding a PCB is position, there is a need to position the PCB with a degree of precision. In a prior art, Japan Patent No. JP6156738B2, teaches a solder printing apparatus with adjustments for the X direction position, the Y direction position, the Z direction position, and the rotation position about the Z axis of the PCB. It also teaches the use of a suction mechanism for holding the PCB in position instead of conventional clamps.

However, the use of a suction mechanism, requires a power source to operate a vacuum pump. With the use of a vacuum system, the solution is susceptible to failure due to leaks, and not having a power supply, to name a few.

As such, a non-powered mechanical system would provide the advantage of not having to be dependent on a power source.

The present invention seeks to overcome the above-mentioned limitations associated with the existing solutions.

### SUMMARY OF INVENTION

In light of the limitations of the existing conventional solutions as discussed above, it is evident that there arises a need a non-powered mechanical system. Furthermore, the present invention provides a clamping mechanism that provides for quick clamp adjustments.

The embodiments of the present disclosure provide a solder printing apparatus comprising a clamping mechanism, and a position adjusting mechanism. The clamping mechanism comprises a mounting base, a lead screw, one or more clamp base, and one or more adjustable height stopper for locating and clamping. The position adjusting mechanism comprises an adjustment for X direction positioning, an adjustment for Y direction positioning, an adjustment for Z direction positioning, and an adjustment for rotation position about the Z axis, each having a turn knob with a micrometer scale, as well as, a position indicator.

In a second aspect of the preferred embodiment the solder printing apparatus comprising a clamping mechanism, a position adjusting mechanism, and a stencil clamp. The clamping mechanism comprises a mounting base, a lead screw, one or more clamp base, and one or more adjustable height stopper for locating and clamping.

The position adjusting mechanism comprises an adjustment for X direction positioning, an adjustment for Y direction positioning, an adjustment for Z direction positioning, and an adjustment for rotation position about the Z axis, each having a turn knob with a micrometer scale, as well as, a position indicator.

The stencil clamp for use with the solder printing apparatus comprises a top clamp frame, a bottom clamp frame, one or more magnet; and one or more guide pin.

In another aspect of the preferred embodiment the solder printing apparatus comprising a clamping mechanism, a position adjusting mechanism, and a centering apparatus. The clamping mechanism comprises a mounting base, a lead screw, one or more clamp base, and one or more adjustable height stopper for locating and clamping.

The position adjusting mechanism comprises an adjustment for X direction positioning, an adjustment for Y direction positioning, an adjustment for Z direction positioning, and an adjustment for rotation position about the Z axis, each having a turn knob with a micrometer scale, as well as, a position indicator.

The centering apparatus for an irregular polygon shaped substrate comprises a track, a rack and pinion mechanism, one or more pin for locating the centering apparatus, a locator, and a turn knob.

### BRIEF DESCRIPTION OF DRAWINGS

The drawings mentioned herein disclose exemplary embodiments of the claimed invention. Detailed description and preparation of well-known compounds/substances/elements are omitted to not unnecessarily obscure the embodiments herein. Other objects, features, and advantages of the present invention will be apparent from the following description when read with reference to the accompanying drawing.

FIG. 1A to FIG. 1B illustrates a schematic illustration of the present invention in accordance with an embodiment of the present disclosure;

FIG. 1C to FIG. 1E illustrates an exemplary illustration of the present invention in accordance with an embodiment of the present disclosure.

FIG. 2A to FIG. 2C illustrates an exemplary illustration of a complement of the present invention in accordance with an embodiment of the present disclosure;

FIG. 3A illustrates an exemplary illustration of the present invention with a complement in accordance with an embodiment of the present disclosure;

FIG. 3B to FIG. 3F illustrates an exemplary illustration of a complement of the present invention in accordance with an embodiment of the present disclosure.

### DETAILED DESCRIPTION

This section is intended to provide explanation and description of various possible embodiments of the present invention. The embodiments used herein, and the various features and advantageous details thereof are explained more fully with reference to non-limiting embodiments illustrated in the accompanying drawing/s and detailed in the following description. The examples used herein are intended only to facilitate understanding of ways in which the embodiments may be practiced and to enable the person skilled in the art to practice the embodiments used herein. Also, the examples/embodiments described herein should not be construed as limiting the scope of the embodiments herein.

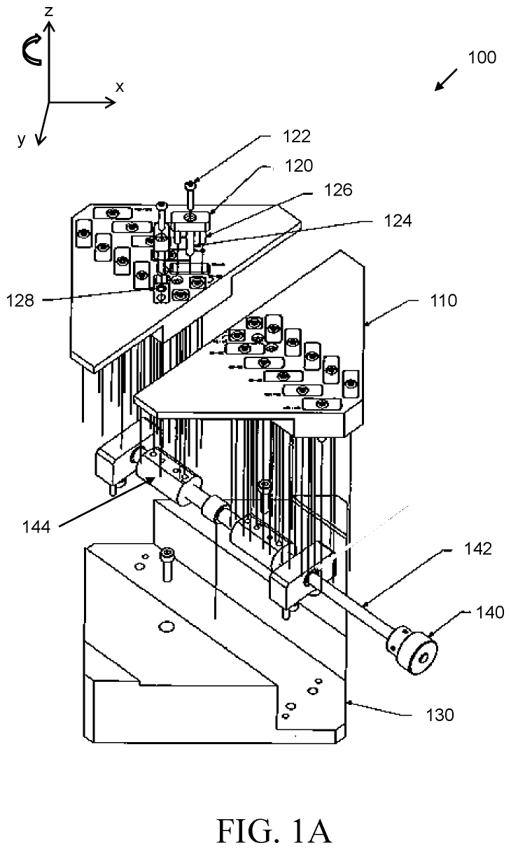

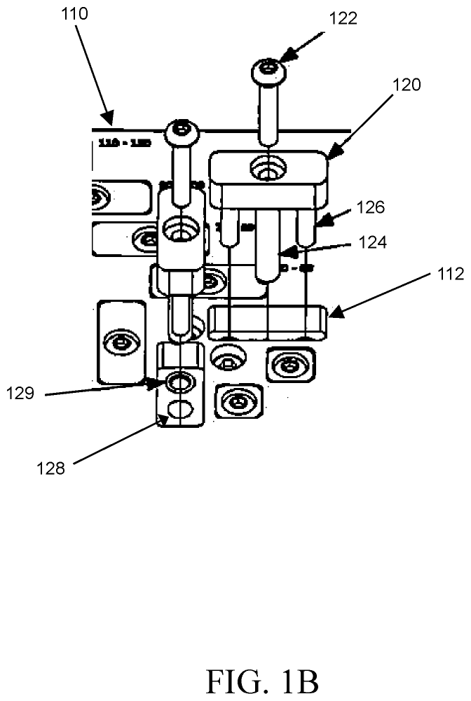

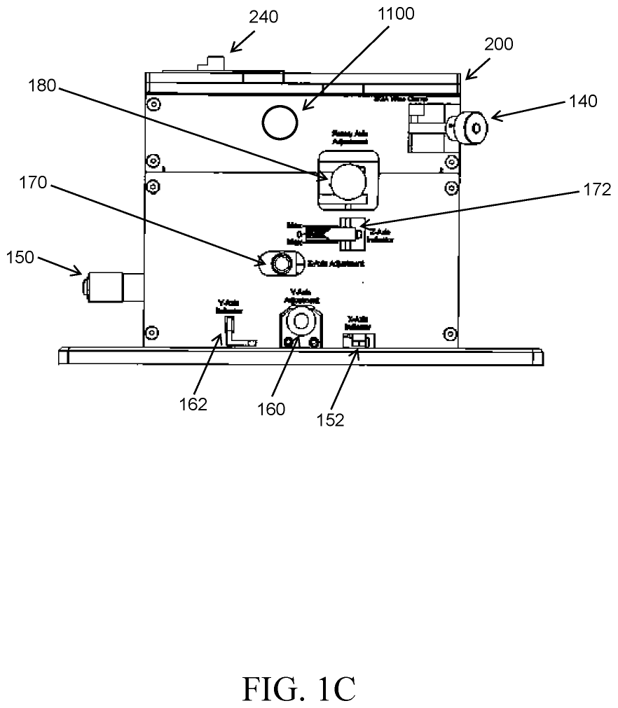

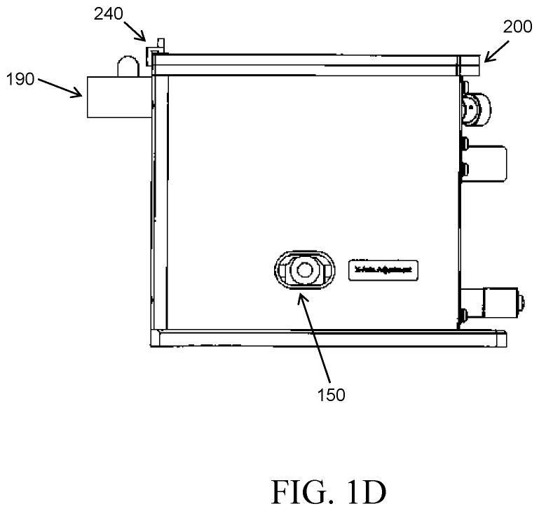

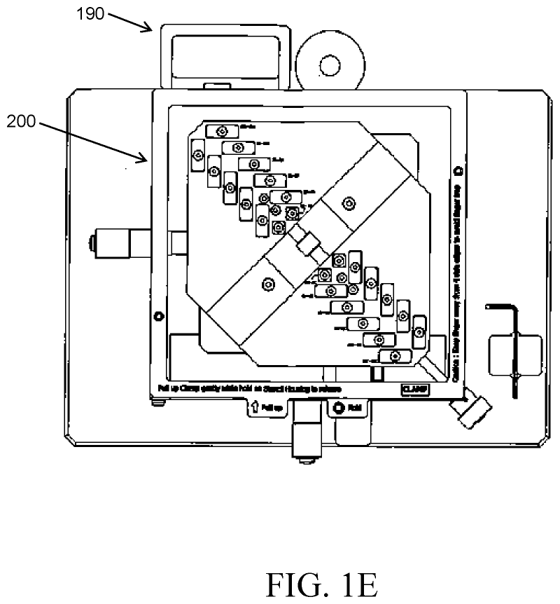

Referring to FIG. 1A to FIG. 1E, a preferred embodiment of the present disclosure provides a solder printing apparatus comprising a clamping mechanism (100), and a position adjusting mechanism. The clamping mechanism (100) comprises a mounting base (130), a lead screw (142), one or more clamp base (110), and one or more adjustable height stopper (120) for locating and clamping. The position adjusting mechanism comprises an adjustment for X direction positioning (150), an adjustment for Y direction positioning (160), an adjustment for Z direction positioning (170), and an adjustment for rotation position about the Z axis (180), each having a turn knob with a micrometer scale, as well as, a position indicator (152, 162, 172).

The micrometer scale allows for precise adjustments of the adjustment for X direction positioning (150), the adjustment for Y direction positioning (160), the adjustment for Z direction positioning (170), and the adjustment for rotation position about the Z axis (180). The X direction position indicator (152), the Y direction position indicator (162), and the Z direction position indicator (172) provide a reference for a known position setting. The position indicator (152, 162, 172) is pointer that indicates a reference position along a scale according to the direction and magnitude of the change.

Referring to FIG. 1A, for a regular polygon shaped printed circuit board (PCB) substrate, for example, a square substrate, a pair of clamp bases (110) are configured to clamp diagonally opposite corners of the substrate. Where a clamp base (110) is connected to a nut (144). And the nut (144) is connected to the lead screw (142). Where the lead screw (142) is operated by a turn knob (140). As such, the distance between the clamp bases (110) are adjustable by operating the turn knob (140).

Referring to FIG. 1B, the adjustable height stopper (120) comprises one or more guide pin (126) for positioning the adjustable height stopper (120) on the clamp base (110), a height adjustment means (122) for setting the height of the adjustable height stopper (120), a helical spring (124).

The height adjustment means (122) can be a bolt or screw. When the use of an adjustable height stopper (120) is not required, the height adjustment means (122) stores the adjustable height stopper (120) in a recess (112) in the clamp base (110). The recess (112) has one or more first aperture (128) to accept the height adjustment means (122). The first aperture (128) has a threaded portion to engage with a threaded portion of the height adjustment means (122). Where the storing of the adjustable height stopper (120) is achievable by tightening the height adjustment means (122). When stored, the top of the adjustable height stopper (120) is preferably flush with the surface of the clamp base (110).

Also, the recess in the clamp base (110) has one or more second aperture (129) to accept the guide pin (126) of the adjustable height stopper (120).

When in use for locating and clamping a substrate, the adjustable height stopper (120) is raised or lowered to the required height by loosening or tightening the height adjustment means (122). Such that, the top of the adjustable height stopper (120) is above the surface of the clamp base (110) when in operation.

The helical spring (124) used with the adjustable height stopper (120) is preferably a compression spring. The helical spring (124) provides support to the adjustable height stopper (120) by providing a lift force when the adjustable height stopper (120) is in use. As such, preventing the adjustable height stopper (120) from lowering due to the effects of gravity. In addition, the helical spring (124) coils over the height adjustment means (122). The helical spring (124) has a specific calculated force to effectively grip a PCB board.

A preferred embodiment having a clamp base (110) with an orthogonal pair of adjustable height stoppers (120) adjacent to another orthogonal pair of adjustable height stoppers (120) aligned in a line parallel to the length of the lead screw (142). Such a configuration enables quick setup of the clamping mechanism (100) when used with various sizes of substrate.

As such, as the adjustable height stoppers (120) are positioned further away from the center of the clamping mechanism (100), larger dimension substrates can be accommodated. Likewise, as the adjustable height stoppers (120) are positioned closer towards the center of the clamping mechanism (100), smaller dimension substrates can be accommodated. Where the appropriate set of adjustable height stoppers (120) are used according to the dimension and shape of a substrate.

Thus, reducing the required workspace to operate the clamping mechanism (100). Due to the clamping mechanism (100) being able to clamp large substrates without necessarily needing a large separation between the clamp bases (110). This comes as a result of having a choice of adjustable height stoppers (120) at various intervals on the clamp bases (110).

The solder printing apparatus further comprises a removable container (190) for collecting waste, excess solder balls, solder paste or a combination thereof.

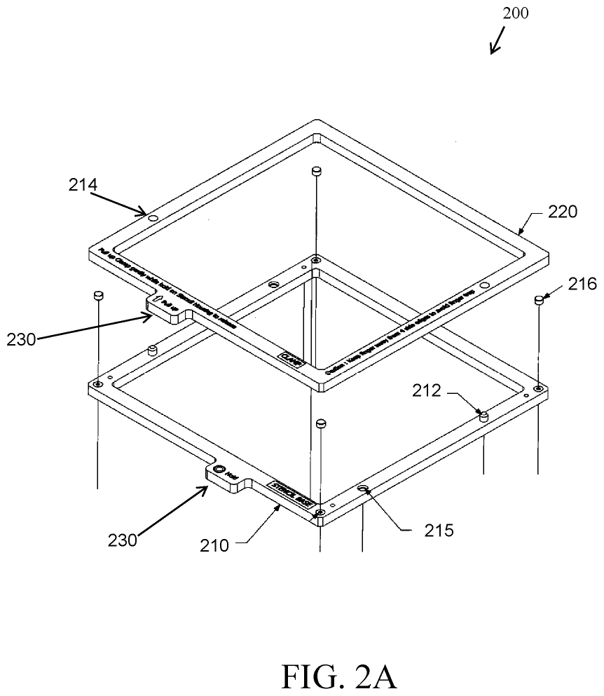

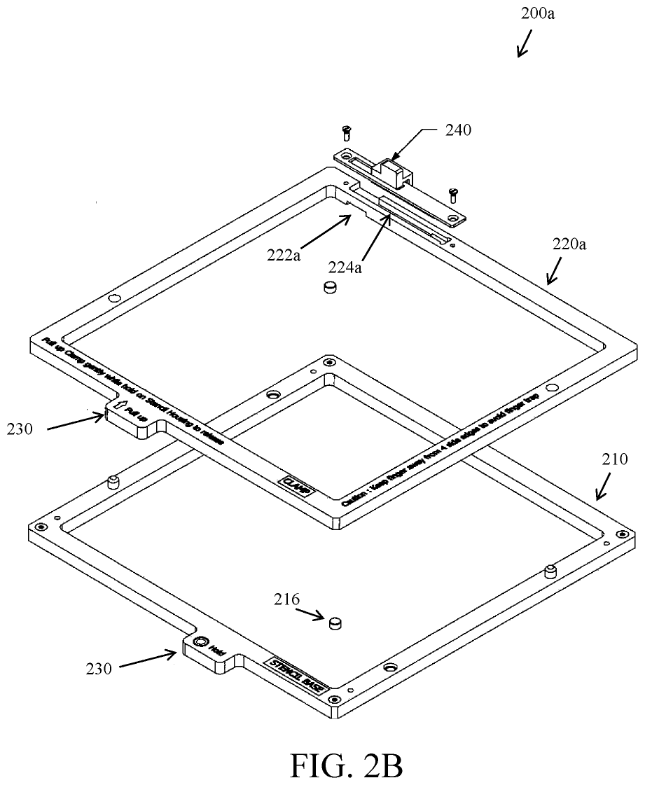

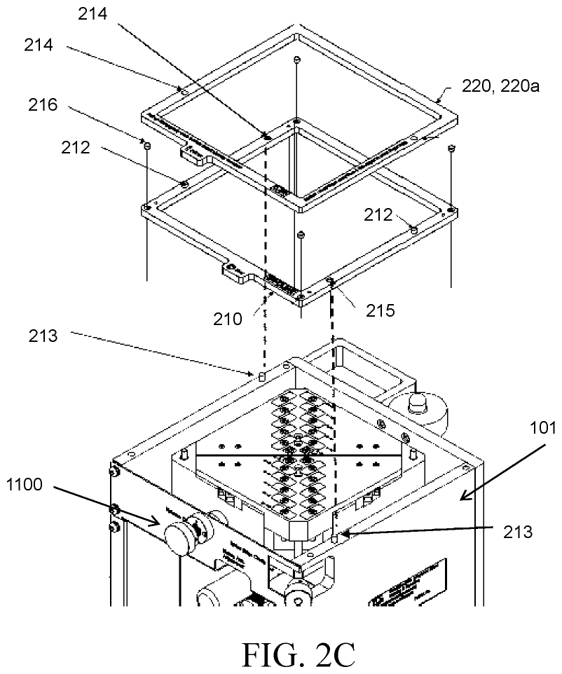

With reference to FIG. 2A to FIG. 2C, the solder printing apparatus further comprises a stencil clamp (200, 200a). The stencil clamp (200, 200a) comprises a top clamp frame (220, 220a) and a bottom clamp frame (210).

The top clamp frame (220, 220a) or bottom clamp frame (210) includes one or more magnet (216). Preferably, the magnet (216) is located at each corner of the frame (210, 220, 220a). If the top clamp frame (220,220a) has the magnets (216), it is not necessary for the bottom clamp frame (210) to have the magnets (216); and vice versa.

If the top clamp frame (220,220a) or the bottom clamp frame (210) do not have the magnets (216), a ferrous or non-ferrous material can preferably be located at each corner of the frame (210, 220, 220a) for strengthening the connection with the magnets (216). A preferred material is nickel or a material that does not rust. The ferrous or non-ferrous material can be a screw, but not limited to such.

The top clamp frame (220,220a) and the bottom clamp frame (210) are preferably made of a material that has superior dimensional stability and flatness. Where the flatness has a tight deviation tolerance of preferably within the range of −0.130 mm to +0.130 mm (ideally zero deviation), but is not limited to the preferred range. Also, having tight thickness tolerances, a pristine surface condition improves the fit and dimensional precision of the top clamp frame (220,220a) and the bottom clamp frame (210).

The top clamp frame (220,220a) and/or the bottom clamp frame (210) have one or more guide pin (212) along a length of one or more side of the frame (210, 220, 220a). The guide pin (212) positions a stencil on either the top clamp frame (220, 220a) or the bottom clamp frame (210), or a combination thereof.

In addition, the top clamp frame (220,220a) and the bottom clamp frame (210) have one or more aperture (214, 215) along a length of one or more side of the frame (210, 220, 220a). Where the guide pin (212) connects to the corresponding aperture (214). As such, the guide pin (212) aligns the top clamp frame (220, 220a) to the bottom clamp frame (210); and vice versa.

The housing (101) of the solder printing apparatus comprises a locating pin (213). Where the locating pin (213) connects with the corresponding aperture (215) of the bottom clamp frame (210) to secure, locate, position, or a combination thereof, the stencil clamp (200, 200a) on the housing (101). The solder printing apparatus can comprise a release cam (1100) for releasing the stencil clamp (200, 200a) from the housing (101).

Further, the top clamp frame (220,220a) and the bottom clamp frame (210) having one or more tab (230). The tab (230) provides aa means to conveniently and easily separate the top clamp frame (220, 220a) from the bottom clamp frame (210); and vice versa. The top clamp frame (220a) comprising a tunnel (222a), a recess (224a), and a gate mechanism (240).

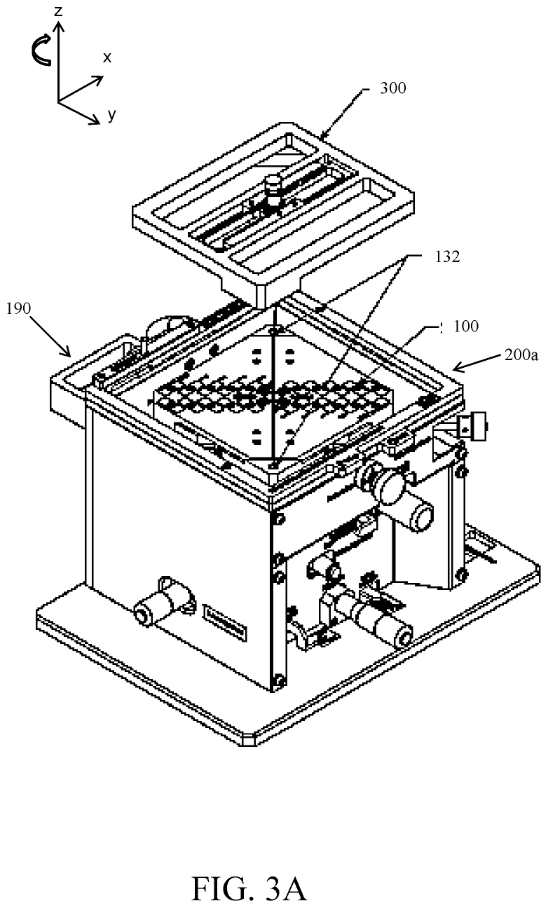

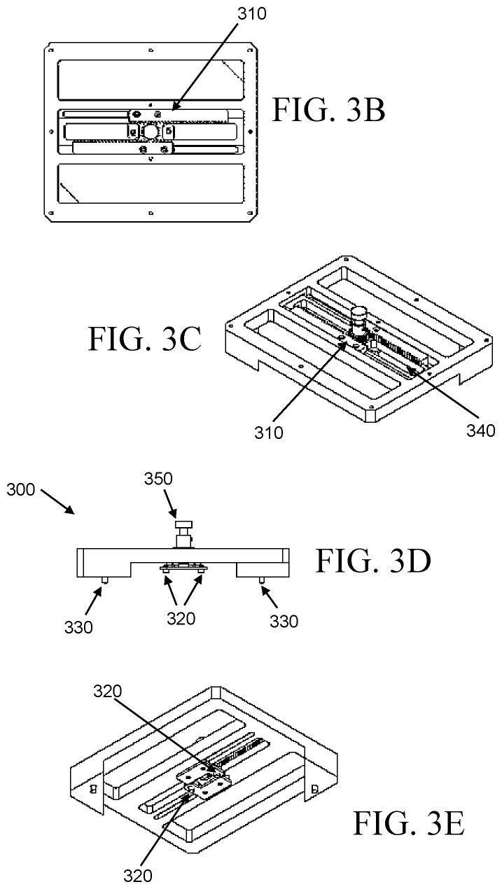

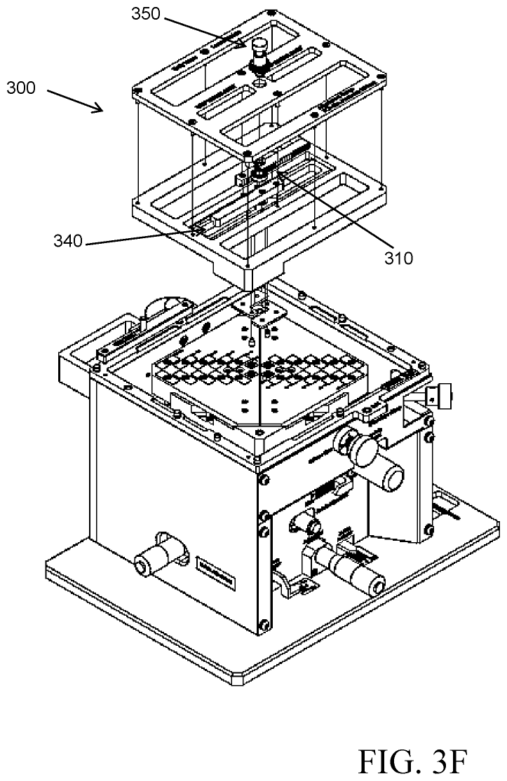

With reference to FIG. 3A to FIG. 3F, the solder printing apparatus further comprising a centering apparatus (300) for an irregular polygon shaped substrate. The centering apparatus (300) comprises a track (340), a rack and pinion mechanism (310), one or more pin (330) for locating the centering apparatus (300), a locator (320), and a turn knob (350). An example of an irregular polygon shaped substrate is a rectangular substrate.

The rack and pinion mechanism (310) comprise a common pinion gear that synchronously drive a pair of racks. Each rack has a locator (320) to guide by pushing the opposing sides of the substrate towards the center of the clamping mechanism (100). As such, the locator (320) guides the substrate to locate the center of the clamping mechanism (100). Operation of the centering apparatus (300) is by the turn knob (350). Where the turn knob (350) operates the common pinion gear.

Furthermore, the mounting base (130) comprises one or more aperture (132) for locating the centering apparatus (300). Where the pin (330) of the centering apparatus (300) connects with the corresponding aperture (132) on the mounting base (130).

In a second aspect of the preferred embodiment the solder printing apparatus comprising a clamping mechanism (100), a position adjusting mechanism, and a stencil clamp (200, 200a). The clamping mechanism (100) comprises a mounting base (130), a lead screw (142), one or more clamp base (110), and one or more adjustable height stopper (120) for locating and clamping.

The position adjusting mechanism comprises an adjustment for X direction positioning (150), an adjustment for Y direction positioning (160), an adjustment for Z direction positioning (170), and an adjustment for rotation position about the Z axis (180), each having a turn knob with a micrometer scale, as well as, a position indicator (152, 162, 172).

The stencil clamp (200, 200a) for use with the solder printing apparatus comprises a top clamp frame (220, 220a), a bottom clamp frame (210), one or more magnet (216); and one or more guide pin (212). The top clamp frame (220, 220a) or bottom clamp frame (210) includes one or more magnet (216). Preferably, the magnet (216) is located at each corner of the frame (210, 220, 220a). If the top clamp frame (220,220a) has the magnets (216), it is not necessary for the bottom clamp frame (210) to have the magnets (216); and vice versa.

The bottom clamp frame (210) can have a ferrous or non-ferrous material preferably located at each corner of the frame (210) for strengthening the connection with the magnets (216). A preferred material is nickel or a material that does not rust. The ferrous or non-ferrous material can be a screw, but not limited to such.

The top clamp frame (220,220a) and the bottom clamp frame (210) have one or more guide pin (212) along a length of one or more side of the frame (210, 220, 220a). The guide pin (212) positions a stencil on either the top clamp frame (220, 220a) or the bottom clamp frame (210), or a combination thereof.

In addition, the top clamp frame (220,220a) and the bottom clamp frame (210) have one or more aperture (214, 215) along a length of one or more side of the frame (210, 220, 220a). Where the guide pin (212) connects to the corresponding aperture (214). As such, the guide pin (212) aligns the top clamp frame (220, 220a) to the bottom clamp frame (210); and vice versa.

The housing (101) of the solder printing apparatus comprises a locating pin (213). Where the locating pin (213) connects with the corresponding aperture (215) of the bottom clamp frame (210) to secure, locate, position, or a combination thereof, the stencil clamp (200, 200a) on the housing (101). The solder printing apparatus can comprise a release cam (1100) for releasing the stencil clamp (200, 200a) from the housing (101).

Further, the top clamp frame (220,220a) and the bottom clamp frame (210) having one or more tab (230). The tab (230) provides aa means to conveniently and easily separate the top clamp frame (220, 220a) from the bottom clamp frame (210); and vice versa. The top clamp frame (220a) comprising a tunnel (222a), a recess (224a), and a gate mechanism (240).

In another aspect of the preferred embodiment the solder printing apparatus comprising a clamping mechanism (100), a position adjusting mechanism, and a centering apparatus (300). The clamping mechanism (100) comprises a mounting base (130), a lead screw (142), one or more clamp base (110), and one or more adjustable height stopper (120) for locating and clamping.

The position adjusting mechanism comprises an adjustment for X direction positioning (150), an adjustment for Y direction positioning (160), an adjustment for Z direction positioning (170), and an adjustment for rotation position about the Z axis (180), each having a turn knob with a micrometer scale, as well as, a position indicator (152, 162, 172).

The centering apparatus (300) for an irregular polygon shaped substrate comprises a track (340), a rack and pinion mechanism (310), one or more pin (330) for locating the centering apparatus (300), a locator (320), and a turn knob (350). An example of an irregular polygon shaped substrate is a rectangular substrate.

The rack and pinion mechanism (310) comprise a common pinion gear that synchronously drive a pair of racks. Each rack has a locator (320) to guide by pushing the opposing sides of the substrate towards the center of the clamping mechanism (100). As such, the locator (320) guides the substrate to locate the center of the clamping mechanism (100). Operation of the centering apparatus (300) is by the turn knob (350). Where the turn knob (350) operates the common pinion gear.

Furthermore, the mounting base (130) comprises one or more aperture (132) for locating the centering apparatus (300). Where the pin (330) of the centering apparatus (300) connects with the corresponding aperture (132) on the mounting base (130).

The housing (101) of the solder printing apparatus comprises a locating pin (213). Where the locating pin (213) connects with the corresponding aperture (215) of the bottom clamp frame (210) to secure, locate, position, or a combination thereof, the stencil clamp (200, 200a) on the housing (101). The solder printing apparatus can comprise a release cam (1100) for releasing the stencil clamp (200, 200a) from the housing (101).

Other devices, such as, a magnifying lens, a lamp, accessory holder, and others can be attached to the solder printing apparatus.

As will be readily apparent to a person skilled in the art, the present invention may easily be produced in other specific forms without departing from its essential composition and properties. The present embodiments should be construed as merely illustrative and non-restrictive and the scope of the present invention being indicated by the claims rather than the foregoing description, and all changes which come within therefore intended to be embraced therein.

1. A solder printing apparatus, comprising:
a clamping mechanism comprises:
a mounting base;
a lead screw;
one or more clamp base; and
one or more adjustable height stopper for locating and clamping;
a position adjusting mechanism comprises:
an adjustment for X direction positioning;
an adjustment for Y direction positioning;
an adjustment for Z direction positioning; and
an adjustment for rotation position about the Z axis.

2. The solder printing apparatus as claimed in claim 1, wherein the adjustment for X direction positioning, the adjustment for Y direction positioning, and the adjustment for Z direction positioning, each having a turn knob with a micrometer scale.

3. The solder printing apparatus as claimed in claim 1, wherein the adjustment for X direction positioning, the adjustment for Y direction positioning, and the adjustment for Z direction positioning, each having a position indicator.

4. The solder printing apparatus as claimed in claim 1, wherein the adjustable height stopper having one or more guide pin for positioning the adjustable height stopper on the clamp base.

5. The solder printing apparatus as claimed in claim 1, wherein the adjustable height stopper having a height adjustment means for setting the height of the adjustable height stopper.

6. The solder printing apparatus as claimed in claim 5, wherein the adjustable height stopper having a helical spring.

7. The solder printing apparatus as claimed in claim 1, comprising a stencil clamp.

8. The solder printing apparatus as claimed in claim 7, wherein the stencil clamp comprises a top clamp frame and a bottom clamp frame.

9. The solder printing apparatus as claimed in claim 8, wherein the top clamp frame includes one or more magnet.

10. The solder printing apparatus as claimed in claim 8, wherein the bottom clamp frame having one or more guide pin.

11. The solder printing apparatus as claimed in claim 10, wherein the guide pin positions a stencil on the bottom clamp frame.

12. The solder printing apparatus as claimed in claim 10, wherein the guide pin aligns the top clamp frame to the bottom clamp frame.

13. The solder printing apparatus as claimed in claim 8, wherein the top clamp frame and the bottom clamp frame having one or more aperture.

14. The solder printing apparatus as claimed in claim 8, wherein the top clamp frame and the bottom clamp frame having one or more tab.

15. The solder printing apparatus as claimed in claim 8, wherein the top clamp frame comprising a tunnel, a recess, and a gate mechanism.

16. The solder printing apparatus as claimed in claim 1, comprising a centering apparatus for an irregular polygon shaped substrate.

17. The solder printing apparatus as claimed in claim 16, wherein the centering apparatus comprises a track, a rack and pinion mechanism, one or more pin for locating the centering apparatus, a locator, and a turn knob.

18. The solder printing apparatus as claimed in claim 17, wherein the mounting base comprises one or more aperture for locating the centering apparatus.

19. A solder printing apparatus, comprising:
a clamping mechanism comprises:
a mounting base;
a lead screw;
one or more clamp base; and
one or more adjustable height stopper for locating and clamping;
a position adjusting mechanism comprises:
an adjustment for X direction positioning;
an adjustment for Y direction positioning;
an adjustment for Z direction positioning; and
an adjustment for rotation position about the Z axis;
a stencil clamp for use with the solder printing apparatus comprising:
a top clamp frame;
a bottom clamp frame;
one or more magnet; and
one or more guide pin.

20. The solder printing apparatus as claimed in claim 19, wherein the guide pin positions a stencil on the bottom clamp frame.

21. The solder printing apparatus as claimed in claim 19, wherein the guide pin aligns the top clamp frame to the bottom clamp frame.

22. The solder printing apparatus as claimed in claim 19, wherein the top clamp frame and the bottom clamp frame having one or more aperture.

23. The solder printing apparatus as claimed in claim 19, wherein the top clamp frame and the bottom clamp frame having one or more tab.

24. The solder printing apparatus as claimed in claim 19, wherein the top clamp frame comprising a tunnel, a recess, and a gate mechanism.

25. A solder printing apparatus, comprising:
a clamping mechanism comprises:
a mounting base;
a lead screw;
one or more clamp base; and
one or more adjustable height stopper for locating and clamping;
a position adjusting mechanism comprises:
an adjustment for X direction positioning;
an adjustment for Y direction positioning;
an adjustment for Z direction positioning; and
an adjustment for rotation position about the Z axis;
a centering apparatus for an irregular polygon shaped substrate comprising:
a track;
a rack and pinion mechanism;
one or more pin for locating the centering apparatus;
a locator; and
a turn knob.

26. The solder printing apparatus as claimed in claim 25, wherein the mounting base comprises one or more aperture for locating the centering apparatus.

27. The solder printing apparatus as claimed in claim 1, comprising a locating pin on a housing of the solder printing apparatus.

28. The solder printing apparatus as claimed in claim 1, wherein the locating pin connects with the corresponding aperture of a bottom clamp frame.

29. The solder printing apparatus as claimed in claim 19, wherein the locating pin connects with the corresponding aperture of the bottom clamp frame.

30. The solder printing apparatus as claimed in claim 1, comprising a release cam.

31. The solder printing apparatus as claimed in claim 1, comprising a removable container for collecting waste, excess solder balls, or a combination thereof.
